(19) United States
(12) Patent Application Publication
(10) Pub. No.: US 2007/0235214 A1
(43) Pub. Date: Oct. 11, 2007

(54) Moisture resistant printed circuit board

(76) Inventors: Stephen H. Hall, Hillsboro, OR (US); Bryce D. Horine, Portland, OR (US); Gary A. Brist, Yamhill, OR (US); Howard Heck, Hillsboro, OR (US)

Correspondence Address: BUCKLEY, MASCHOFF & TALWALKAR LLC, 50 LOCUST AVENUE, NEW CANAAN, CT, 06840, US

(21) Appl. No.: 11/393,329

(22) Filed: Mar. 30, 2006

(51) Int. Cl. H05K 1/00; H05K 1/03

(52) U.S. Cl. 174/258; 174/255

(57) ABSTRACT

A printed circuit board structure includes a plurality of layers. The plurality of layers includes at least one metal layer or partial metal layer and at least one dielectric layer of a first type. The plurality of layers also includes two dielectric layers of a second type that is different from the first type. The at least one dielectric layer of the first type is between the two dielectric layers of the second type. The dielectric layers of the second type have a moisture absorption characteristic not in excess of 0.1%.

### BACKGROUND

Signal loss associated with printed circuit boards (PCBS) is a significant issue as data transmission speeds increase. In particular, with increasing data transmission rates, dielectric loss is coming to exceed conductor (skin effect) loss. The dielectric loss properties of epoxy based PCB materials tend+ to vary with the moisture content of the material. Dielectric loss tends to be low in dry conditions, but may substantially increase in humid environments. For PCBs in equipment operated in humid environments, moisture content may increase over time, leading potentially to increased channel loss and degraded performance.

### BRIEF DESCRIPTION OF THE DRAWINGS

FIG. 1 is an exploded view of a PCB structure according to some embodiments.

FIG. 2 is an isometric view of the PCB structure of FIG. 1.

FIG. 3 is a flow chart that illustrates a process for fabricating the PCB structure.

FIG. 4 is a simplified schematic side cross-sectional view of the PCB structure.

FIG. 5 is a view similar to FIG. 4, showing the PCB structure after edge-sealing.

FIG. 6 is an isometric view of another embodiment of the PCB structure.

FIG. 7 is an isometric view of still another embodiment of the PCB structure.

### DETAILED DESCRIPTION

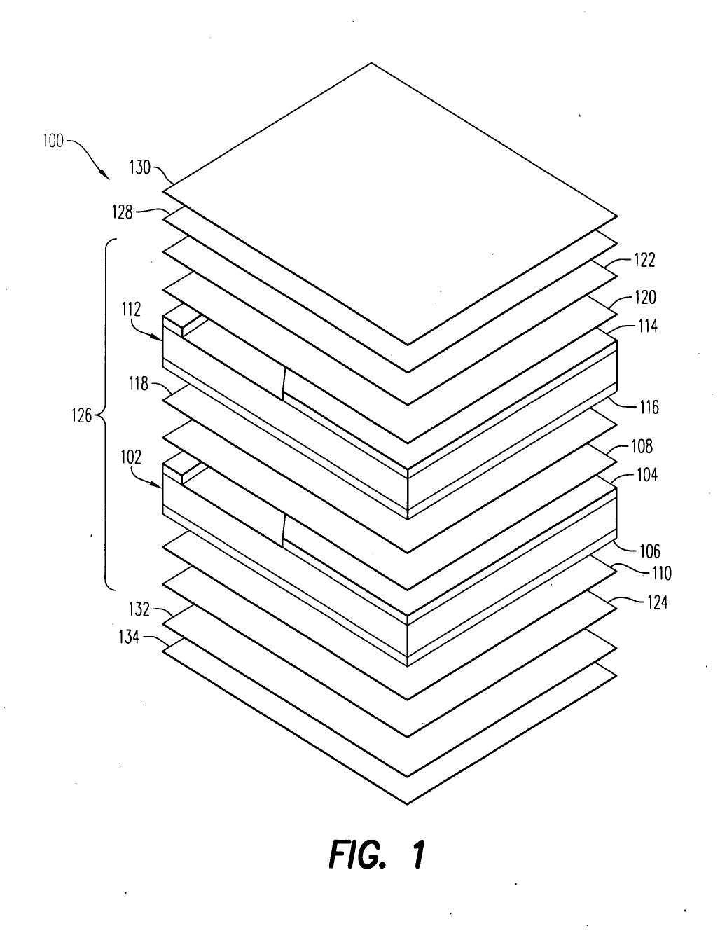

FIG. 1 is an exploded view of a PCB structure 100 according to some embodiments. As used herein and in the appended claims, “PCB structure” or “printed circuit board structure” refers to a finished PCB or to a structure comprising one or more layers of material, with an additional layer or layers to be added and/or with one or more processes to be performed to turn the structure into a finished PCB. It will be observed that the PCB structure 100 is formed of a number of layers, including for example a first core layer 102 formed of a conventional PCB dielectric material such as FR4. Metal layers (or partial layers) 104 and 106 are formed, respectively, on the top and bottom surfaces of the core layer 102. A layer 108 of FR4 “prepreg” (i.e., a pre-impregnated fiberglass or other fabric impregnated with the FR4 epoxy system) may be provided above the metal layer 104, and another layer 110 of FR4 prepreg may be provided below the metal layer 106.

The PCB structure 100 may also include another core layer 112, which may also be formed of FR4, above core layer 102 and its accompanying metal and prepreg layers. Once again, metal layers (or partial layers) 114, 116 may respectively be formed on the top and bottom surfaces of core layer 112. A prepreg layer 118 may be provided between metal layer 116 and prepreg layer 108. Still another prepreg layer 120 may be provided above metal layer 114. Still further prepreg layers 122 and 124 may be provided, respectively, above prepreg layer 120 and below prepreg layer 110.

In accordance with conventional practices, the metal layers or partial metal layers referred to up to this point may serve as signal trace layers and/or ground planes or power planes. Some or all of the metal layers/partial layers may be formed of copper, in accordance with conventional practices.

The PCB layers described up to this point may collectively be referred to a “intermediate layers” 126. It will be observed that the intermediate layers 126 are positioned between a second layer 128 (which is immediately below a top layer 130) and a penultimate layer 132 (which is immediately above a bottom layer 134). In other words, the intermediate layers 126 are below the second layer 128; the penultimate layer 132 is below the intermediate layers 126, and the bottom layer 134 is immediately below the penultimate layer 132.

The second layer 128 and the penultimate layer 132 may be formed of a moisture resistant dielectric to prevent or greatly reduce absorption of moisture by the intermediate layers 126. As used herein, “moisture resistant” is a short-hand expression to indicate that the material in question has a moisture absorption characteristic not in excess of 0.1%. “Moisture absorption characteristic”, in turn, as used herein and in the appended claims, is defined as the percent of absorption figure measured in accordance with IPC Test Method 650 2.6.2, promulgated May 1998 by the Institute for Interconnecting and Packaging Electronic Circuits (IPC), Northbrook, Ill. The second layer 128 and the penultimate layer 132 may, for example, be formed of a liquid crystal polymer (LCP) dielectric having a moisture absorption characteristic of substantially 0.04%. This is in contrast to FR4 or other conventional PCB epoxy dielectrics which may have a moisture absorption characteristic of about 0.3% to 0.8%.

The top layer 130 and the bottom layer 134 may be metal layers, e.g., copper foil. It should be noted that the intermediate layers 126 plus the moisture resistant layers 128, 132 (i.e., the structure 100 less the metal layers 130 and 134) may itself be considered a PCB structure having the moisture resistant layers 128, 132 as top and bottom layers, respectively.

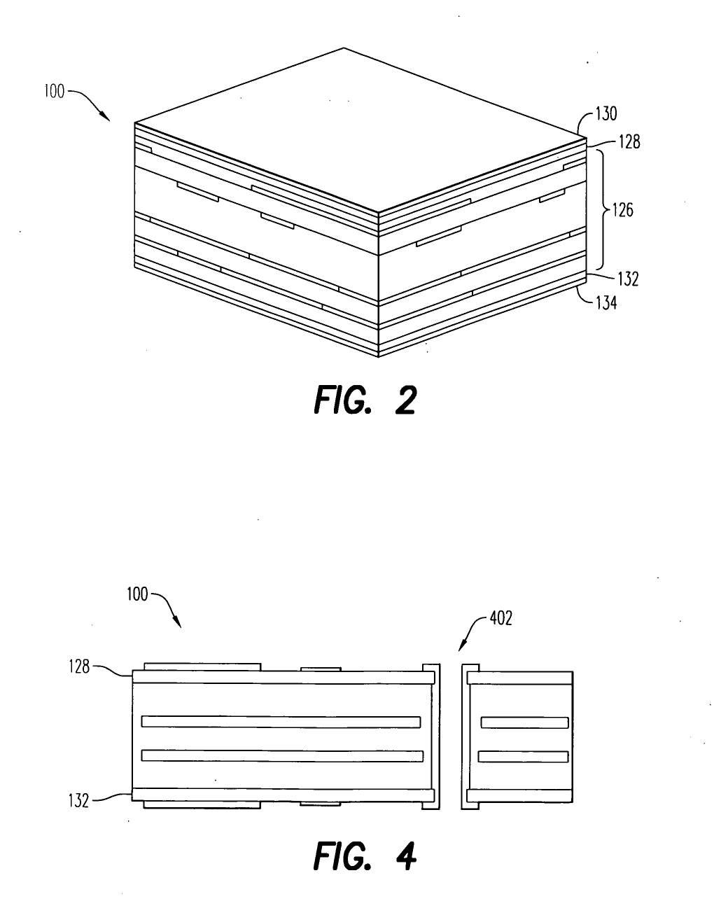

FIG. 2 is an isometric view of the PCB structure 110 shown in assembled form. It should be understood that the number and/or types of intermediate layers 126 may vary from those shown in FIGS. 1 and 2. Moreover, one or both of the foil layers 130, 134 may be omitted. The dielectric layers within the intermediate layers 126 need not be FR4, but may for example alternatively be of any other material conventionally employed as a dielectric for a PCB.

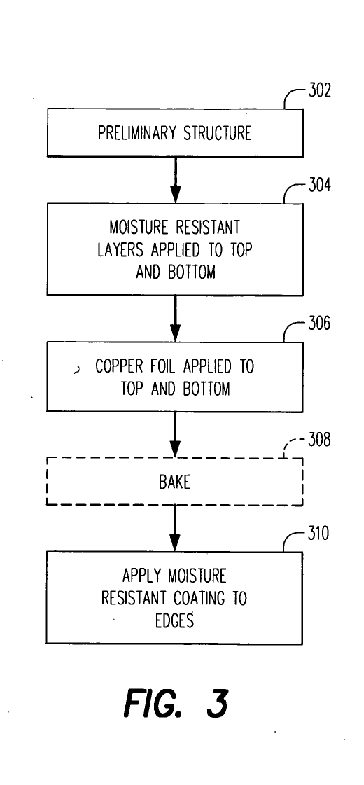

FIG. 3 is a flow chart that illustrates a process for fabricating the PCB structure 100. At 302 in FIG. 3, a preliminary structure such as the intermediate layers 126 is provided. At 304, the moisture resistant layers 128, 132 are applied, respectively, to the top and bottom of the preliminary structure. At 306, copper foil is applied to the top and bottom of the structure resulting from 304. At 308, optionally, a baking procedure is applied to the structure resulting from 306 to expel from the dielectric layers of the intermediate layers some or all of any moisture that may have been absorbed therein prior to the baking procedure. Then, following 308, or directly following 306, as the case may be, the edges of the PCB structure are coated with a moisture resistant material (as indicated at 310 in FIG. 3) to complete the sealing against moisture absorption of the dielectric layers of the intermediate layers. As used herein and in the appended claims, the “edges” of the PCB structure refer to surfaces of the PCB structure that are substantially normal to the plane of the PCB structure. FIG. 3 and the accompanying description are not meant to imply a fixed order of performing the process stages; rather, the process stages may be performed in any order that is practicable. For example, the layers may be laminated or applied to each other in any order that is practicable.

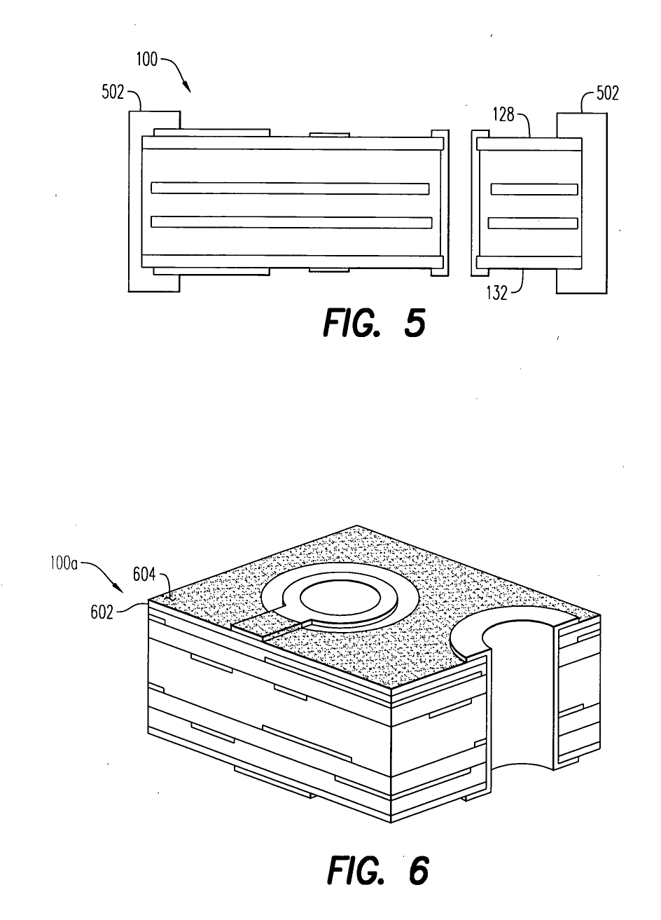

FIG. 4 is a schematic cross-sectional view of the PCB structure prior to performance of the edge coating stage 310 (FIG. 3). In addition to features such as the moisture resistant layers 128, 132, FIG. 4 shows other features of the PCB structure such as a via 402. FIG. 5 is a view similar to FIG. 4, but showing the PCB structure after the moisture resistant coating 502 has been applied to the edges of the structure. Although only two edges of the PCB structure are represented in FIGS. 4 and 5, it should be understood that the moisture resistant coating may be applied to all four edges (assuming the structure has a conventional rectangular planar shape) of the PCB structure to provide for effective sealing against moisture absorption by the inner dielectric layers. The moisture resistant coating may be LCP. As alternatives to LCP for the moisture resistant coating and/or the moisture resistant layers, materials such as acrylics, silicones or fluoroacrylics may be used.

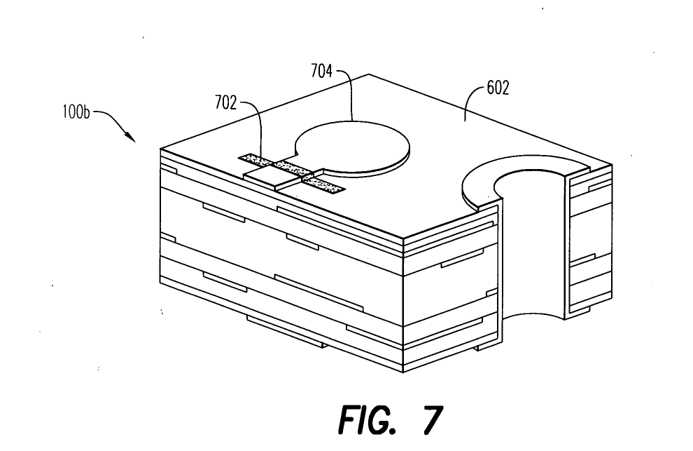

FIG. 6 is an isometric view of another embodiment, suitable for providing a microstrip structure rather than a stripline structure. In FIG. 6, the PCB structure 100a includes a moisture resistant layer 602 immediately below a top, soldermask layer 604. In another microstrip embodiment 100b, shown in FIG. 7, the moisture resistant layer 602 is present, but the soldermask layer is omitted, except for a small soldermask strip 702 near a solderpad 704 to keep solder from wicking away from solderpad 704. In still other embodiments, which are not shown, the soldermask material itself may be selected to be moisture resistant, or the microstrip channel may be coated with a conventional metal surface finish such as immersion silver. Coating of the edges of the microstrip PCB structures may be performed in similar fashion to that illustrated in FIG. 5.

In some embodiments, the moisture content and hence the signal loss characteristics of each PCB may be tuned by dry-baking the board prior to sealing. Alternatively, wet-baking may be applied prior to sealing to increase the moisture content if so desired. With dry-baking prior to sealing, variations in performance between boards and/or over time may be controlled, and such variations may be substantially reduced or eliminated.

The several embodiments described herein are solely for the purpose of illustration. The various features described herein need not all be used together, and any one or more of those features may be incorporated in a single embodiment. Therefore, persons skilled in the art will recognize from this description that other embodiments may be practiced with various modifications and alterations.

What is claimed is:

1. A printed circuit board structure comprising a plurality of layers, the plurality of layers including at least one metal layer or partial metal layer, at least one dielectric layer of a first type, and two dielectric layers of a second type different from said first type, said at least one dielectric layer of said first type being between said two dielectric layers of said second type, said dielectric layers of said second type having a moisture absorption characteristic not in excess of 0.1%.

2. The printed circuit board structure of claim 1, wherein the dielectric layers of said second type have a moisture absorption characteristic of substantially 0.04%.

3. The printed circuit board structure of claim 2, wherein the dielectric layers of the second type are formed of liquid crystal polymer (LCP).

4. The printed circuit board structure of claim 1, wherein one of the dielectric layers of the second type is a top layer of said structure and the other of the dielectric layers of the second type is a bottom layer of said structure.

5. The printed circuit board structure of claim 1, wherein one of the dielectric layers of the second type is above all layers of said structure, except for a metal layer above said one of the dielectric layers of the second type, and the other of the dielectric layers of the second type is below all layers of said structure, except for a metal layer below said other of the dielectric layers of the second type.

6. The printed circuit board structure of claim 5, wherein the metal layers are formed of copper and the at least one dielectric layer of the first type is formed of FR4 core.

7. The printed circuit board structure of claim 6, further comprising at least one layer of FR4 prepreg located between said two dielectric layers of the second type.

8. The printed circuit board structure of claim 1, further comprising a coating applied to edges of said structure, said coating having a moisture absorption characteristic not in excess of 0.1%.

9. The printed circuit board structure of claim 8, wherein said coating has been applied to substantially all edges of said structure.

10. The printed circuit board structure of claim 8, wherein said coating is liquid crystal polymer (LCP).

11. The printed circuit board structure of claim 1, wherein said at least one dielectric layer of the first type has a moisture absorption characteristic substantially in excess of 0.1%.

12. The printed circuit board structure of claim 11, wherein said at least one dielectric layer of the first type has a moisture absorption characteristic of at least 0.3%.

13. A method comprising:
providing a preliminary printed circuit board structure, the preliminary printed circuit board structure comprising a plurality of layers, said plurality of layers including at least one dielectric layer of a first type and at least one metal layer or partial metal layer;
applying a first layer of a dielectric of a second type, different from the first type, to a top surface of the preliminary printed circuit board structure; and
applying a second layer of a dielectric of a second type to a bottom surface of the preliminary printed circuit board structure;
wherein the dielectric of the second type has a moisture absorption characteristic not in excess of 0.1%.

14. The method of claim 13, wherein the dielectric of the first type has a moisture absorption characteristic substantially in excess of 0.1%.

15. The method of claim 14, wherein the dielectric of the first type has a moisture absorption characteristic of at least 0.3%.

16. The method of claim 13, further comprising:
applying a metal layer to the first layer of dielectric of the second type and applying a metal layer to the second layer of the dielectric of the second type.

17. The method of claim 13, further comprising:
after applying said metal layers, coating edges of the preliminary printed circuit board structure with a dielectric that has a moisture absorption characteristic not in excess of 0.1%.

18. A printed circuit board structure comprising:
a top layer formed of copper;
a second layer immediately below the top layer and formed of a first material, said first material being a dielectric having a moisture absorption characteristic not in excess of 0.1%;
a plurality of intermediate layers below the second layer, the plurality of intermediate layers including at least one dielectric layer having a moisture absorption characteristic of at least 0.3%, the plurality of intermediate layers also including at least one metal layer or partial metal layer;
a penultimate layer below the plurality of intermediate layers, the penultimate layer formed of the first material; and
a bottom layer immediately below the penultimate layer and formed of copper.

19. The printed circuit board structure of claim 18, further comprising:
a coating on edges of the structure, the coating having a moisture absorption characteristic not in excess of 0.1%.

20. The printed circuit board structure of claim 19, wherein:
the at least one dielectric layer of the intermediate layers includes at least one layer of FR4; and
the first material is liquid crystal polymer (LCP).
